(19) United States
(12) Patent Application Publication
(10) Pub. No.: US 2020/0049503 A1
(43) Pub. Date: Feb. 13, 2020

(54) INFORMATION PROCESSING DEVICE, INFORMATION PROCESSING METHOD, AND DATA STRUCTURE

(71) Applicant: SHARP KABUSHIKI KAISHA, Sakai City (JP)

(72) Inventor: SHIGEO OHYAMA, Sakai City (JP)

(21) Appl. No.: 16/536,324

(22) Filed: Aug. 9, 2019

Related U.S. Application Data
(60) Provisional application No. 62/718,022, filed on Aug. 13, 2018.

(51) Int. Cl. G01C 17/38; G01R 35/00; G01C 17/02; G01R 33/02

(52) U.S. Cl. CPC G01C 17/38; G01R 33/0206; G01C 17/02; G01R 35/005

(57) ABSTRACT

[Object] An information processing device that calibrates offset and distortion with good precision, with a small amount of computation.

[Solution] Provided is a mesh control unit (22) that generates a mesh that sections, into a plurality of regions, an orientation space where pieces of magnetism data collected from a magnetic sensor (11) are arrayed, based on components of the magnetism data, and stores the magnetism data in a storage unit (30) for each section. The number of sections in contact with a vertex of each of the multiple of sections is three or less.

### TECHNICAL FIELD

The present invention relates to an information processing device, an information processing method, and a data structure.

### BACKGROUND ART

In recent years, evolution of mobile equipment such as smartphones and the like has led to increase in demand for electronic compasses, such as pedestrian navigation and so forth. Electronic compasses measure magnetic flux density of geomagnetism by magnetic sensors using Hall elements, MR elements (Magneto-Resistive elements), MI elements (Magneto-Impedance elements), and so forth, and point to the magnetic north.

However, geomagnetism is not very strong, and accordingly is readily affected by the surrounding environment. Moreover, mobile equipment has a great number of parts installed that generate magnetism, such as speaker, coils, and so forth, besides the magnetic sensor. The direction and so forth of geomagnetism measured by the magnetic sensor is thrown off due to the influence of parts that generate magnetism. This deviation is referred to as the hard-iron effect, and is manifested as offset when collecting magnetism data, as illustrated in FIG. 12. Also, distortion occurs in magnetic fields due to metal with a high permeability. This distortion is referred to as the soft-iron effect, and a set of magnetism data that should be spherical when collecting magnetism data is distorted into an ellipsoid, as illustrated in FIG. 13. In order to point to an accurate magnetic north with an electronic compass or the like, the magnetic sensor needs to be used with these offset and distortion calibrated.

In order to obtain offset and distortion, first, magnetism data is collected while changing the direction of the equipment. A solid plotted by the collected magnetism data is approximated to an ellipsoid by the least-square method or the like, and this ellipsoid is converted so as to be a sphere with a center at zero. Accordingly, it is important that pieces of the magnetism data be uniformly distributed in order to accurately approximate the ellipsoid.

PTL 1 obtains magnetism data for obtaining offset and distortion by selecting magnetism data from newly-obtained magnetism data, based on an evaluation function indicating distance to already-existing magnetism data. Repeating the above process gradually increases the distance as to magnetism data for obtaining offset and distortion, so desired magnetism data can be obtained.

PTL 2 picks four pieces of magnetism data for obtaining offset and distortion, from which a spherical surface that is a magnetism data group passing through the four pieces of magnetism data is obtained, and offset is obtained from this spherical surface. If a tetrahedron of which the vertices are the four pieces of magnetism data is a regular tetrahedron, error in offset can be minimized, so calculation is performed to pick the four pieces of magnetism data.

PTL 3 accumulates measurement data output from an orientation sensor in each section of an orientation space, while updating each section. Offset data is then updated based on multiple pieces of measurement data that have been accumulated.

### CITATION LIST

### Patent Literature

[PTL 1] Japanese Unexamined Patent Application Publication “Japanese Unexamined Patent Application Publication No. 2013-195195” publication
[PTL 2] Japanese Unexamined Patent Application Publication “Japanese Unexamined Patent Application Publication No. 2007-107921” publication
[PTL 3] Japanese Patent Publication “Japanese Patent No. 4311447” publication

### SUMMARY OF INVENTION

### Technical Problem

However, in order to determine magnetism data for obtaining offset and distortion, the inventions disclosed in PTLs 1 through 3 (i) need great amounts of magnetism data and acceleration data. Accordingly, in order to determine desired magnetism data using the above technique, (ii) there is a need to repeatedly perform computation, and the amount of computation becomes great.

### Solution to Problem

(1) An embodiment of the present invention is an information processing device that collects magnetism data from a magnetic sensor. The device includes a mesh control unit that generates a mesh that sections, into a plurality of regions, an orientation space where pieces of the magnetism data collected from the magnetic sensor are arrayed, based on components of the magnetism data, and stores the magnetism data for each section in a storage unit. A number of sections in contact with a vertex of each of the plurality of sections is three or less.

(2) Also, an embodiment of the present invention is an information processing device that, in addition to the configuration of the (1) above, further includes a determining unit that determines whether or not to continue collection of the magnetism data from the magnetic sensor, based on a number of sections storing a predetermined count of the magnetism data, out of the plurality of sections.

(3) Also, an embodiment of the present invention is an information processing device where, in addition to the configuration of the (2) above, the determining unit discards magnetism data collected after a count of the magnetism data stored in each of the plurality of sections reaches the predetermined count or greater.

(4) Also, an embodiment of the present invention is an information processing device where, in addition to the configuration of the (2) above, the determining unit performs notification processing to a user in a case where a number of sections not storing the predetermined count of the magnetism data, out of the plurality of sections, is smaller than a threshold value.

(5) Also, an embodiment of the present invention is an information processing device that, in addition to the configuration of the (1) above, further includes magnetic sensor that outputs the magnetism data, an acceleration sensor that outputs acceleration data, and an attitude computing unit that collects each of the magnetism data and the acceleration data, and performs attitude computation before the mesh control unit generates the mesh.

(6) Also, an embodiment of the present invention is an information processing device where, in addition to the configuration of the (1) above, the magnetism data includes values of a plurality of axes as the coordinate components. The information processing device further includes a calibration computing unit that computes a difference between a maximum value and minimum value of each of the plurality of axes, from a plural pieces of magnetism data.

(7) Also, an embodiment of the present invention is an information processing device where, in addition to the configuration of the (1) through (6) above, where the mesh control unit stores the magnetism data in the storage unit, in association with identification information for identifying each of the plurality of sections, and a count of the magnetism data stored in each of the plurality of sections.

(8) An embodiment of the present invention is information processing method of an information processing device that collects magnetism data from a magnetic sensor. The method includes a mesh control step of generating a mesh that sections, into a plurality of regions, an orientation space where pieces of the magnetism data collected from the magnetic sensor are arrayed, based on components of the magnetism data, and storing the magnetism data for each section in a storage unit. In the mesh control step, sectioning is performed in which a number of sections in contact with a vertex of each of the plurality of sections is three or less.

(9) Also, an embodiment of the present invention is an information processing method that, in addition to the configuration of the (8) above, further includes a determining step of determining whether or not to continue collection of the magnetism data from the magnetic sensor, based on a number of sections not storing a predetermined count of the magnetism data, out of the plurality of sections.

(10) Also, an embodiment of the present invention is an information processing method where, in addition to the configuration of the (9) above, in the determining step, after a count of the magnetism data stored in each of the plurality of sections reaches the predetermined count or greater, the newest magnetism data stored in this section is discarded.

(11) Also, an embodiment of the present invention is an information processing method where, in addition to the configuration of the (9) above, in the determining step, notification processing to a user is performed in a case where sections not storing the predetermined count of the magnetism data, out of the plurality of sections, is smaller than a threshold value.

(12) Also, an embodiment of the present invention is an information processing method that, in addition to the configuration of the (8) above, further includes an attitude computing step in which attitude computation is performed using the magnetism data and acceleration data obtained from an acceleration sensor, before the mesh control step.

(13) Also, an embodiment of the present invention is an information processing method where, in addition to the configuration of the (8) above, the magnetism data includes values of a plurality of axes as the coordinate components. The method further includes a calibration computing step in which a difference between a maximum value and minimum value of each of the plurality of axes is computed.

(14) Also, an embodiment of the present invention is an information processing method where, in addition to the configuration of the (8) through (13) above, in the mesh control step, the magnetism data is stored in the storage unit, in association with identification information for identifying each of the plurality of sections, and a count of the magnetism data stored in each of the plurality of sections.

(15) Also, an embodiment of the present invention is an data structure that stores magnetism data collected by a magnetic sensor. Section data indicating a plurality of sections obtained by dividing an orientation space where pieces of the magnetism data are arrayed, based on coordinate components of the magnetism data, and a count of magnetism data stored in each of the sections, are stored. The section data and the count of the magnetism data are used by an information processing device, in processing of determining whether or not to continue collection of the magnetism data, based on a number of sections storing a predetermined count of the magnetism data.

(16) Also, an embodiment of the present invention is a data structure where, in addition to the configuration of the (15) above, an upper limit value of a count of the magnetism data stored in each of the plurality of sections is stored. The upper limit value is used as a determination reference for processing of discarding magnetism data collected after the count of the magnetism data has reached the upper limit value or higher, out of the magnetism data stored in each of the sections in the information processing device.

(17) An embodiment of the present invention is a computer-readable recording medium in which is recorded an information processing program that causes a computer to function as the information processing device according to the (1) above, the information processing program causing a computer to function as the mesh control unit.

### Advantageous Effects of Invention

The present invention can provide an information processing device that can precisely calibrate offset and distortion of a magnetic sensor with a small amount of computation.

### BRIEF DESCRIPTION OF DRAWINGS

FIG. 1 is a block diagram of the configuration of an information processing device according to Embodiment 1.

FIG. 2 is a diagram illustrating an example of attitude computation according to Embodiment 1.

FIG. 3A is a diagram in which a mesh is generated by sectioning a mesh with dividing lines in the longitudinal direction shifted, so that intersecting portions of dividing lines in the latitudinal direction and dividing lines in the longitudinal direction do not overlap in crosses.

FIG. 3B is a diagram in which longitudinal direction dividing lines of the sections of the mesh illustrated in FIG. 3A are drawn without being shifted from the zenith to the nadir of the sphere.

FIG. 4 is a diagram illustrating an example of a data table of magnetism data collected in a mesh in a storage unit according to Embodiment 1.

FIG. 5 is a diagram illustrating an example of dividing mesh sections in the latitudinal direction, according to Embodiment 1.

FIG. 6 is a diagram illustrating an example of dividing mesh sections in the longitudinal direction, according to Embodiment 1.

FIG. 7 is a flowchart of a magnetism data collection method according to Embodiment 1.

FIG. 8 is a block diagram of the configuration of a magnetic sensor calibration device according to Embodiment 2.

FIG. 9 is a diagram illustrating a detectable range before prior calibration, according to Embodiment 2.

FIG. 10 is a diagram illustrating a detectable range after prior calibration, according to Embodiment 2.

FIG. 11 is a flowchart of a magnetism data collection method according to Embodiment 2.

FIG. 12 is a diagram illustrating the hard-iron effect.

FIG. 13 is a diagram illustrating the soft-iron effect.

### DESCRIPTION OF EMBODIMENTS

### Embodiment 1

For the sake of convenience in description, configurations having the same functions as a configuration described with regard to a particular item are denoted by the same characters, and description thereof will be omitted. This point is true regarding Embodiment 2 as well. Also, devices such as an information processing device, control device, and so forth, in an aspect of the present invention, may be singular or may be plural in the embodiments.

Further, information processing devices that are the object of application of the present invention are various types of electronic equipment such as flip phones, wearable terminals, small gaming devices, tablet terminals, and so forth, besides smartphones that are exemplified below. In other words, information processing devices that are the object of application of the present invention may be any arrangement as long as electronic equipment that has a magnetic sensor such as an electronic compass or the like.

In the present embodiment, mesh means an arrangement where an orientation sphere, which is the shape of a set of magnetism data coordinate components, has been sectioned into a mesh form. Magnetism data is recorded in a storage unit 30 that will be described later for each mesh. Note that depending on the state of implementation, a circular shape where a set of magnetism data has been two-dimensionally projected may be sectioned into a mesh form, instead of sectioning a sphere that is the shape of a set of magnetism data into a mesh form. The shape of two-dimensional projection may be elliptical instead of circular. Also, in a case where the magnetic sensor and acceleration sensor are a biaxial magnetic sensor and biaxial acceleration sensor instead of triaxial, an orientation circle can be sectioned into a mesh form instead of an orientation sphere.

[Information Processing Device]

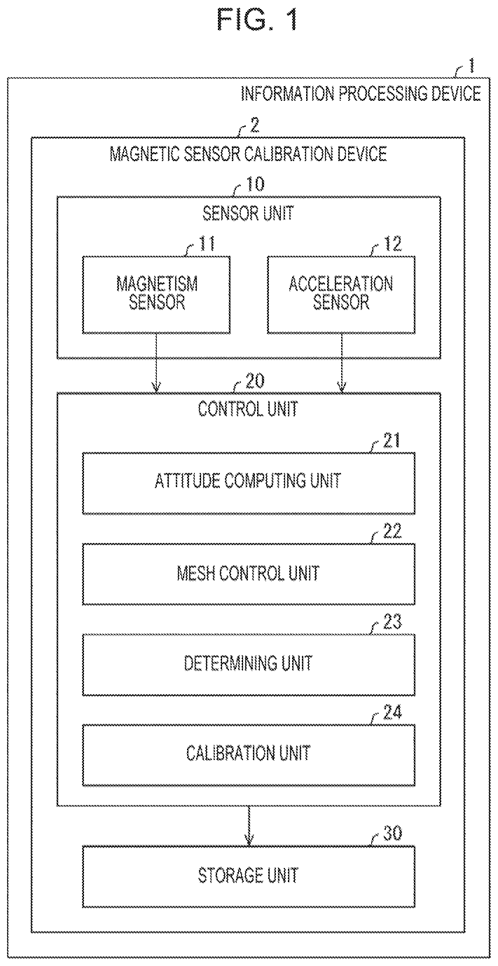

FIG. 1 is a block diagram illustrating the configuration of an information processing device 1 according to the present embodiment. The information processing device 1 according to the present embodiment has a magnetic sensor calibration device 2. The magnetic sensor calibration device 2 has a sensor unit 10, a control unit 20, and the storage unit 30.

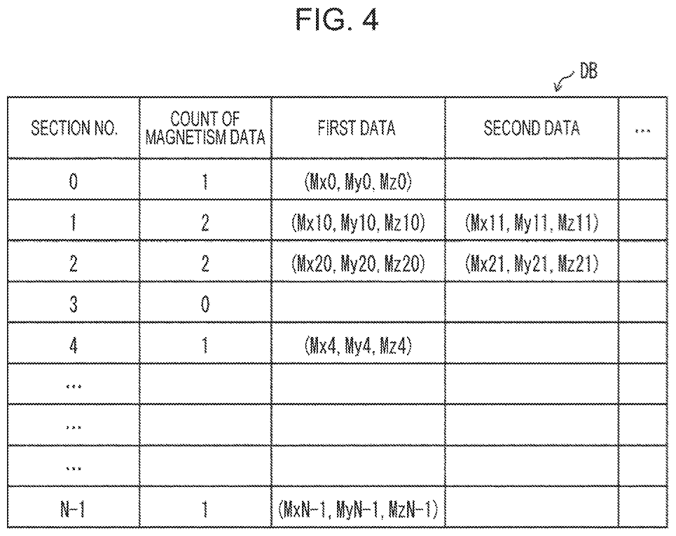

The sensor unit 10 has two types of sensors, a magnetic sensor 11 and an acceleration sensor 12. The magnetic sensor 11 successively obtains magnetism data, and outputs the obtained magnetism data to the control unit 20. The acceleration sensor 12 successively obtains acceleration data, and outputs the obtained acceleration data to the control unit 20. The control unit 20 has an attitude computing unit 21, a mesh control unit 22, a determining unit 23, and a calibration unit 24. The control unit 20 obtains magnetism data over time from the magnetic sensor 11, and obtains acceleration data over time from the acceleration sensor 12. The storage unit 30 is memory that can be configured of RAM (Random Access Memory) or ROM (Read Only Memory) or the like. A database DB that will be described later (FIG. 4) is stored in the storage unit 30.

(About Attitude Computation)

The attitude computing unit 21 collects each of magnetism data and acceleration data, and performs attitude computation before the mesh control unit 22 generates the mesh. The attitude computing unit 21 computes the attitude (roll angle (ψ), pitch angle (θ), yaw angle (Ψ)) of the magnetic sensor calibration device 2, from the two types of data, which are the magnetism data obtained by the magnetic sensor 11 and the acceleration data obtained by the acceleration sensor 12. The mesh control unit 22 generates a mesh where the orientation space is divided into multiple sections based on coordinate components of the magnetism data obtained by the magnetic sensor 11, and stores magnetism data associated with each section in the storage unit 30. In other words, sections divided by the mesh generated by the mesh control unit 22 is used at the time of storing magnetism data in the storage unit 30. The determining unit 23 determines whether or not to continue to collect magnetism data and acceleration data. The determining unit 23 also determines whether or not to save the collected magnetism data and acceleration data. The calibration unit 24 calibrates offset and distortion using the data stored in the storage unit 30, which will be described later.

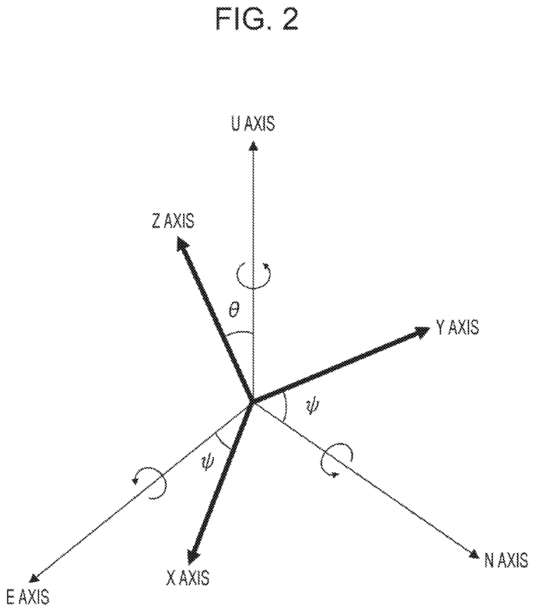

FIG. 2 is a diagram illustrating an example of attitude computation relating to Embodiment 1. Attitude computation of the magnetic sensor calibration device 2 is processing performed by the attitude computing unit 21. Description will be made here assuming that the magnetic sensor 11 is a triaxial magnetic sensor, and the acceleration sensor 12 is a triaxial acceleration sensor. That is to say, the magnetism data that the magnetic sensor 11 has obtained and the acceleration data that the acceleration sensor 12 has obtained each have coordinate components (coordinate data) with the XYZ axes that are coordinate axes of the orientation space being axial components. The coordinate components (coordinate data) that magnetism data has will be written as (Mx, My, Mz). The coordinate components (coordinate data) that acceleration data has will be written as (Ax, Ay, Az).

Note that the orientation space is a vector space where output values obtained from the magnetic sensor 11 and acceleration sensor 12 are plotted as coordinate data. That is to say, this means a vector space defining positions, where output values of the respective axes of XYZ corresponding to the intensity of geomagnetism of each direction component of the X, Y, and Z axes, are coordinate components.

The attitude computing unit 21 first detects the direction in which gravity is acting, from the acceleration data obtained by the acceleration sensor 12, and takes the detected direction in which gravity is acting as a U axis. The horizontal component of the magnetic sensor is obtained from the U axis, and is taken as an N axis. Further, an axis orthogonal to each of the U axis and N axis is taken as an E axis. The attitude (roll angle (ψ), pitch angle (θ), yaw angle (Ψ)) is calculated in accordance with the above-described ENU axes, from the acceleration data and magnetism data divided into the respective axis components of XYZ. Accordingly, expression of attitude according to the ENU axes can be expressed by the following Math. 1 through Math. 4.

$$\begin{matrix}Pitch ( θ ) = {tan}^{- 1} ( - \frac{Ax}{\sqrt{{Ay}^{2} + {Az}^{2}}} ) & [ Math . 1 ] \\ Roll ( ϕ ) = {tan}^{- 1} ( \frac{Ay}{Az} ) & [ Math . 2 ] \\ Yaw ( ψ ) = {tan}^{- 1} ( - \frac{{My}^{′}}{{Mx}^{′}} ) & [ Math . 3 ] \\ ( \begin{matrix}{Mx}^{′} \\ {My}^{′} \\ {Mz}^{′}\end{matrix} ) = ( \begin{matrix}cos θ & sin ϕ sin θ & cos ϕ sin θ \\ 0 & cos ϕ & - sin ϕ \\ - sin θ & sin θ cos ϕ & cos ϕ cos θ\end{matrix} ) ( \begin{matrix}Mx \\ My \\ Mz\end{matrix} ) & [ Math . 4 ]\end{matrix}$$

(About Sectioning by Mesh)

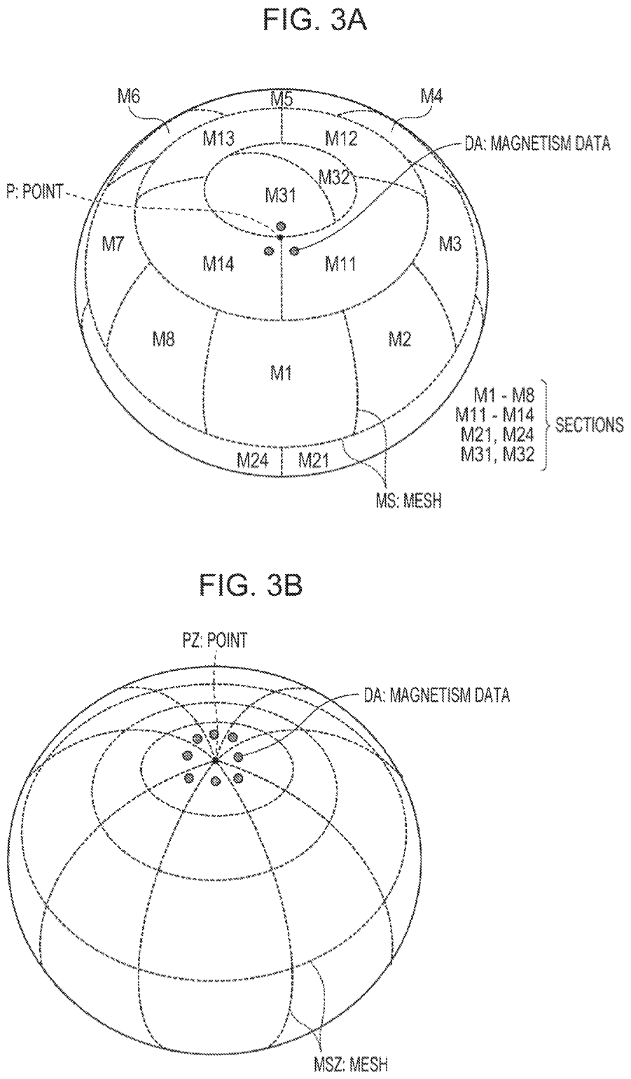

The mesh that the mesh control unit 22 generates will be described with reference to FIG. 3A, FIG. 3B and FIG. 4, but the generating method of the mesh that the mesh control unit 22 generates is not particularly restricted to the following description.

FIG. 3A is a diagram representing the way in which an orientation sphere is divided into a plurality of sections according to Embodiment 1, and FIG. 3B is a diagram representing the way in which an orientation sphere is divided into a plurality of sections according to a comparative example. In FIG. 3B, dividing lines in the longitudinal direction are drawn from the zenith to the nadir of the orientation sphere, without being shifted. Accordingly, intersecting portions of the dividing lines in the latitudinal direction and the dividing lines in the longitudinal direction overlap in crosses in the mesh illustrated in FIG. 3B. Accordingly, there are cases where there are four adjacent sections, and cases where there are eight adjacent sections. Particularly, at the zenith and nadir, at points where the dividing lines in the longitudinal direction congregate (hereinafter referred to as point PZ), the number of sections adjacent centered on the point PZ is eight.

Accordingly, pieces of magnetism data DA stored in each of the adjacent sections centered on the point PZ tend to be pieces of magnetism data DA similar to each other in coordinate components, and the distribution range of the measured magnetism data DA becomes narrow. Accordingly, the precision of offset calibration of the magnetic sensor calibration device 2 becomes low.

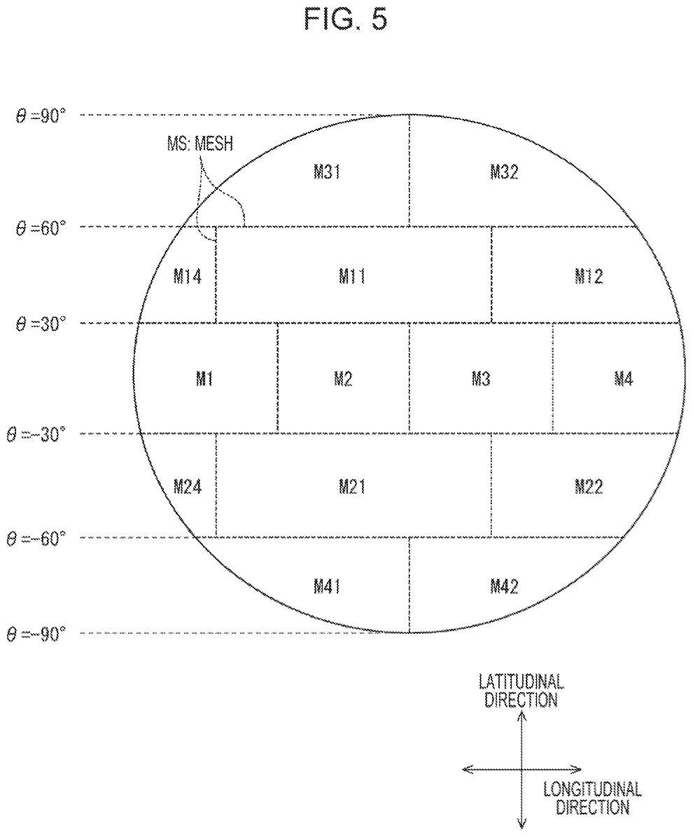

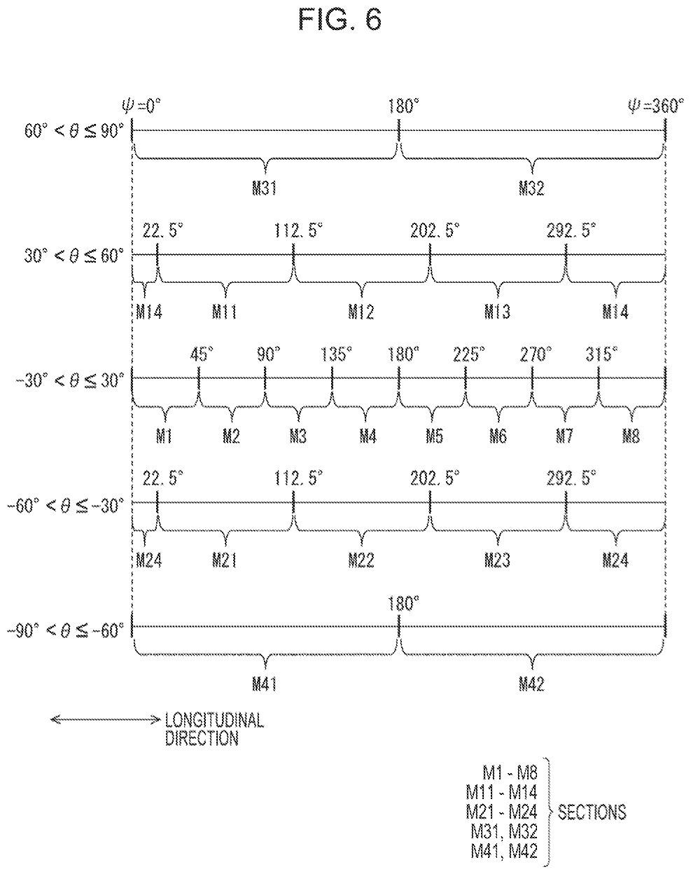

On the other hand, the mesh control unit 22 divides the orientation sphere into multiple sections by generating a mesh MS with dividing lines in the longitudinal direction having been shifted, so that intersecting portions of the dividing lines in the latitudinal direction and the dividing lines in the longitudinal direction do not overlap in crosses on the orientation sphere, as illustrated in FIG. 3A. Here, the mesh control unit 22 sections the orientation sphere into sections M1 through M8, M11 through M14, M21 through M24, M31, M32, M41, and M42 (see FIG. 5 and FIG. 6 for sections M22, M23, M41, and M42).

Accordingly, the number of adjacent sections at a point where the dividing lines in the latitudinal direction and the dividing lines in the longitudinal direction intersect (hereinafter referred to as point P) is three, in the mesh MS illustrated in FIG. 3A. Thus, the count of magnetism data DA in the proximity of the point P is three. For example, the three sections of section M11, section M14, and section M31 are adjacent with each other at the point P that is a vertex of each. The count of magnetism data DA stored in the section M11 and section M14 and section M31 near to the point P is three each.

By performing sectioning as illustrated in FIG. 3A, the number of adjacent sections is three or less at all points P. Accordingly, the possibility of collecting plurality of magnetism data having similar coordinate components can be reduced. The shape of sectioning may be rectangular shapes where the orientation sphere is sliced into round slices in the latitudinal direction and divided in the longitudinal direction as described above, for example, or may be other shapes. The section area of each section preferably is the same or maximally without difference, in order to improve calculation precision and reduce data collection time.

Note that while description has been made regarding the dividing lines described above, where dividing lines in the longitudinal direction are shifted to perform sectioning, dividing lines in the latitudinal direction may be shifted depending on the situation of implementation. Also, the position of the zenith may be set to a position other than the top.

As described above, the mesh control unit 22 divides the orientation space into multiple sections by generating the mesh MS that sections the orientation space into multiple regions, and stores magnetism data in the storage unit 30 in association with each of the sections. Each of the multiple sections obtained by the mesh control unit 22 dividing the orientation space (specifically, an orientation sphere) by the mesh MS has three or less sections in contact with a vertex. Accordingly, plurality of magnetism data having similar coordinate components can be suppressed from being stored in the storage unit 30 and saved. As a result, the computation precision of the magnetic sensor calibration device 2 can be improved, and the magnetism data collection time can be reduced.

The mesh control unit 22 may generate the mesh MS so that the area of each section obtained by division by the mesh MS is the same. Accordingly, the calculation precision of the magnetic sensor calibration device 2 can be improved, and the magnetism data collection time can be reduced. Also, the number of sections in contact with the point P are three or less, due to performing sectioning by shifting the dividing lines in the longitudinal direction so that the dividing lines in the latitudinal direction and the dividing lines in the longitudinal direction do not overlap in crosses at the point P, as described above. Accordingly, the possibility of collecting similar magnetism data can be reduced, and precise calibration can be performed with little data.

(Determining Unit 23)

When the mesh control unit 22 stores magnetism data for each section in the storage unit 30, the determining unit 23 determines whether or not to save this magnetism data. Specifically, the determining unit 23 sets an upper limit value (predetermined count) to the count of magnetism data to be stored in one section. The determining unit 23 then discards the magnetism data collected after the count of magnetism data stored in each of the multiple sections reaches the upper limit value (predetermined count) or higher. Thus, the upper limit value (predetermined count) is used by the information processing device 1 as a determination reference for processing to discard magnetism data collected after the count of magnetism data reaches the upper limit value or higher out of magnetism data stored in each of the sections. According to the above configuration, the amount of data used for offset and distortion computation of the magnetism data can be suppressed by suppressing the count of magnetism data stored in one section. Note that the upper limit value (predetermined count) may be stored in the storage unit 30, or may be stored in memory different from the storage unit 30.

The determining unit 23 also determines whether or not the count of magnetism data stored in one section is lacking. In a case where the count of magnetism data stored is lacking in a particular section, the user may be notified of the section No. where the count of magnetism data is lacking, and the count of magnetism data that is lacking, for example. In other words, in a case where the number of sections where a predetermined count of magnetism data is not stored, out of the multiple sections, is equal to or greater than a threshold value set beforehand, the determining unit 23 may perform notification processing to the user. Note that notification processing is processing of making a predetermined display to notify the user on a display in a case where the information processing device 1 has a display, outputting predetermined audio to notify the user from a speaker in a case where the information processing device 1 has a speaker, or the like.

According to the above configuration, the amount of data used for computation to calculate offset and distortion of the magnetism data can be suppressed by setting a threshold value regarding the count of magnetism data to be stored in one section of the mesh. Also, the number of sections where the count of magnetism data is lacking can be easily reduced, by prompting the user to collect magnetism data for the section where magnetism data is lacking.

Further, the determining unit 23 may determine whether or not to continue collection of magnetism data from the magnetic sensor 11, based on the number of sections where a predetermined count of magnetism data is not stored, out of the multiple sections. That is to say, when the number of sections where a predetermined count of magnetism data is not stored out of the multiple sections decreases, and is smaller than the predetermined threshold value that has been set beforehand, the determining unit 23 may cause the control unit 20 to stop collecting magnetism data from the magnetic sensor 11. When the control unit 20 stops collecting magnetism data from the magnetic sensor 11, the calibration unit 24 then calibrates offset and distortion. Accordingly, collecting more magnetism data than necessary can be prevented, and the calibration unit 24 can be made to promptly perform calibration of offset and distortion.

(Calibration Unit 24)

The calibration unit 24 calibrates offset and distortion of the magnetic sensor calibration device 2 using the magnetism data and acceleration data stored in the storage unit 30, which will be described later. The method of calibration that the calibration unit 24 carries out is not restricted in particular, and various conventional methods can be used. Also, data used for computation for performing calibration may be just one of the magnetism data and acceleration data.

(Database DB)

FIG. 4 is a diagram illustrating an example of the database DB of magnetism data, where the collected magnetism data is stored in the storage unit 30 according to the present embodiment. The mesh control unit 22 generates the database DB illustrated in FIG. 4. The mesh control unit 22 stores magnetism data in the storage unit 30, in association with identification information identifying each of the multiple selections, and the count of magnetism data stored in each of the multiple sections. Specifically, the database DB of magnetism data illustrated in FIG. 4 is a table where section Nos. (identification information, section data) have been allocated to each section obtained by dividing by the mesh, and the count of magnetism data stored in association with each section No. and coordinate components of each magnetism data have been associated with each other. In the example illustrated in FIG. 4, the section No., the count of magnetism data included in a coordinate region of a section identified by this section No., and each coordinate component of magnetism data included in the coordinate region of the section identified by this section No., are associated with each other in the database DB. Note that it is sufficient for the identification information allocated to each section to be information whereby the sections can be identified, and is not restricted to numerals, and may be letters, characters, or a combination thereof or the like.

In other words, the data structure stored in the information processing device 1 is a data structure that stores magnetism data collected by the magnetic sensor, and stores section data indicating the multiple sections obtained by dividing the orientation space, and the count of magnetism data stored for each of the sections. It can be said that the number of the section data and the count of the magnetism data are used by the information processing device 1 in processing for determining whether or not to continue collection of magnetism data, based on the number of sections storing a predetermined count of magnetism data.

[Mesh Sections]

A specific example of a method of generating the mesh that the mesh control unit 22 generates will be described below. FIG. 5 is a diagram illustrating a side view of an orientation sphere that has been sectioned into five equal parts at a pitch angle θ of the orientation sphere by dividing lines in the latitudinal direction. Note that the orientation sphere is spherical, and accordingly sections are formed in the range not illustrated in FIG. 5 as well.

Sections M1 through M8 are sections obtained by the range of the orientation sphere where the pitch angle θ is −30θ<θ≤30θ being equally divided into eight by the mesh MS. Also, sections M11 through M14 are sections obtained by the range of the orientation sphere where the pitch angle θ is 30θ<θ≤60θ being equally divided into four. Also, sections M21 through M24 are sections obtained by the range of the orientation sphere where the pitch angle θ is −60°<θ≤−30θ being equally divided into four. Also, sections M31 and M32 are sections obtained by the range of the orientation sphere where the pitch angle θ is 90°≤θ>60° being equally divided into two. Also, sections M41 and M42 are sections obtained by the range of the orientation sphere where the pitch angle θ is −90°<θ≤−60° being equally divided into two.

FIG. 6 is a diagram illustrating an example of dividing the orientation sphere by the yaw angle Ψ in the longitudinal direction by the mesh MS. Note that in FIG. 6, description will be made using a number line for each range of pitch angle θ of the orientation sphere described in FIG. 5. The scale marks on the number lines indicate the yaw angle Ψ, with the mesh MS being drawn in the longitudinal direction according to the numerals listed at the scale marks.

The orientation sphere is equally divided into the eight sections M1 through M8 in the range where the pitch angle θ is −30°<θ≤30°. Accordingly, the mesh MS was drawn in the longitudinal direction at 0 degrees, 45 degrees, 90 degrees, 135 degrees, 180 degrees, 225 degrees, 270 degrees, and 315 degrees in yaw angle Ψ. Also, the sphere is equally divided into the four sections M11 through M14 in the range where the pitch angle θ is 30θ<θ≤60°. Accordingly, the mesh MS was drawn in the longitudinal direction at 22.5 degrees, 112.5 degrees, 202.5 degrees, and 292.5 degrees, in yaw angle Ψ. The mesh MS was drawn in the longitudinal direction in the range where the pitch angle of the orientation sphere is −60°<θ≤−30°, in the same way as with the range 30°<θ≤60°, thus equally dividing the sphere into the four sections M21 through M24. Also, the orientation sphere is equally divided into the two sections M31 and M32 in the range where the pitch angle θ is 90°≥θ>60°. Accordingly, dividing lines were drawn in the longitudinal direction at 0 degrees and 180 degrees, in yaw angle Ψ. The mesh MS was drawn in the longitudinal direction in the range where the pitch angle θ of the sphere is −90°<θ≤−60°, in the same way as with the range 90°≥θ>60°, thus equally dividing the sphere into the two sections M41 and M42.

According to the configuration above, the surface of the orientation sphere can be divided into multiple sections such that the number of sections adjacent to one vertex is three or less, by generating the mesh MS shifted in the longitudinal direction so that intersecting portions of the dividing lines in the latitudinal direction and the dividing lines in the longitudinal direction do not overlap in crosses. Accordingly, the possibility of collecting magnetism data having similar coordinate components can be reduced.

[Information Collecting Method]

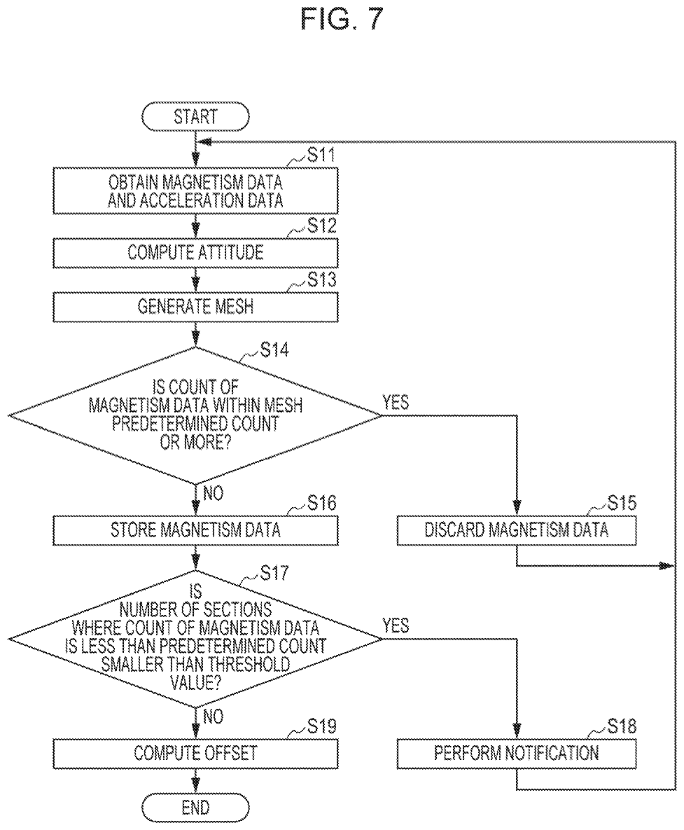

An information processing method using the information processing device 1 according to the present embodiment will be described below. FIG. 7 is a diagram representing a flowchart of the information processing method that the information processing device 1 according to Embodiment 1 executes.

In step S11, the control unit 20 obtains magnetism data from the magnetic sensor 11, and obtains acceleration data from the acceleration sensor 12. Note that in a case where a triaxial magnetic sensor and a triaxial acceleration sensor are used as the magnetic sensor 11 and acceleration sensor 12, the control unit 20 obtains magnetism data and acceleration data by the information processing device 1 in which the magnetic sensor calibration device 2 is installed being moved three-dimensionally by a user or the like.

Next, in step S12, the attitude computing unit 21 computes the attitude (roll angle ψ, pitch angle θ, yaw angle Ψ) of the information processing device 1 from the magnetism data and acceleration data obtained in step S11 (attitude computing step).

In step S13, the mesh control unit 22 then generates a mesh MS for dividing the orientation space, from the magnetism data and acceleration data obtained in step S11, thereby dividing the orientation space into multiple sections (mesh control step). The mesh control unit 22 generates the mesh MS here so that the number of sections in contact with each vertex is three or less at each of the multiple sections. Note that just magnetism data may be used or just acceleration data may be used, as long as the mesh MS can be generated. Upon having generated the mesh MS, the respective section Nos. of the multiple sections obtained by division by the mesh MS, and magnetism data stored in each of the sections are associated with each other by the mesh control unit 22, and the mesh control unit 22 further compiles a database DB in which the count of magnetism data stored in each section are counted and the counted count is associated, and stores the database DB in the storage unit 30.

Next, in steps S14 through S16, the determining unit 23 references the database DB, and determines whether or not to continue collecting magnetism data from the magnetic sensor 11, based on the number of sections storing a predetermined count of magnetism data (a count of magnetism data of the magnetic sensor 11 necessary for offset and distortion computation), out of the multiple sections (determining step).

Specifically, the determining unit 23 references the database DB in step S14, and determines whether or not the count of magnetism data stored in each of the multiple sections has reached the predetermined count or more. In a case of having determined in step S14 that the count of magnetism data stored in each of the multiple sections has reached the predetermined count or more (case of Yes in step S14), the determining unit 23 discards the magnetism data collected after reaching the predetermined count or more (Step S15), and the control unit 20 obtains magnetism data and acceleration data again. That is to say, the flow returns to the processing of step S11. On the other hand, in a case of the determining unit 23 having determined in step S14 that the count of magnetism data stored in each of the multiple sections is smaller than the predetermined count (case of No in step S14), the mesh control unit 22 stores the magnetism data in sections determined to be smaller than the predetermined count (step S16). Further, the mesh control unit 22 recounts the count of magnetism data stored in the sections where this magnetism data has been newly stored, and overwrites and saves the database DB. Thus, processing of setting an upper limit value (predetermined count) of the count of magnetism data stored in one section, and discarding without storing the newly collected magnetism data after reaching the upper limit value or more, is performed in steps S14 through S16.

Next, the determining unit 23 references the database DB in step S17, and determines whether or not the number of sections not storing the predetermined count of magnetism data out of the multiple sections is smaller than a threshold value set beforehand.

In a case of having determined in step S17 that the number of sections not storing the predetermined count of magnetism data out of the multiple sections is smaller than the threshold value (a case of Yes in step S17), the determining unit 23 performs notification processing to the user (step S18). The user may be notified to collect magnetism data for the sections regarding which the count of magnetism data is lacking in this step S18. For example, notification processing to the user may be performed by the determining unit 23 displaying an arrow on a display screen of the display that the information processing device 1 has, to move the information processing device 1 in an appropriate direction, so as to cause the user to collect magnetism data to be included in sections regarding which the count of magnetism data is lacking. Alternatively, notification processing to the user may be performed by the section Nos. of sections where the count of magnetism data is lacking, and the count of lacking magnetism data, being displayed on the display screen of the display.

On the other hand, upon the determining unit 23 having determined in step S17 that the number of sections not storing the predetermined count of magnetism data out of the multiple sections is equal to or greater than the threshold value (a case of No in step S17), the calibration unit 24 performs offset computation (step S19). That is to say, in step S19, the calibration unit 24 references the database DB, and performs offset and distortion computation based on the magnetism data included in the database DB. Conventional methods can be used for the computation method regarding offset and distortion computation that this calibration unit 24 performs.

Thus, according to the information processing device 1 of the present embodiment, the mesh control unit 22 generates the mesh MS so that the number of sections in contact with a vertex is three or less for each of the multiple sections. Accordingly, the vector distance among magnetism data stored in association with each section can be made to be long in comparison with a case of generating a mesh where the number of sections in contact with a vertex is four or more for each of the multiple sections. In other words, the coordinates of magnetism data stored in the storage unit 30 can be broadly dispersed, so offset and distortion can be accurately computed. As a result, the offset and distortion of the magnetic sensor 11 can be obtained with a small amount of computation, and an accurate magnetic sensor calibration device 2 can be provided.

(Specific Flow of Magnetism Data Collection)

Processing up to carrying out offset and distortion computation processing will be described below by way of specific example. Assumption will be made that in step S13, the mesh control unit 22 has divided the orientation sphere into a total of 80 sections by the mesh MS. The predetermined count to be stored in each of the multiple sections (upper limit value) is then set to two, for example, beforehand. Also, the threshold value for the number of sections, regarding which offset computation is determined to be performed even if the count of magnetism data is lacking, is set to eight, for example.

First, the mesh control unit 22 stores magnetism data in each section. At this time, as magnetism data continues to be collected, the determining unit 23 determines whether there are sections occurring where a count of two of magnetism data has been stored (step S14). In response to this, in a case where magnetism data has been newly collected for a section where two pieces of magnetism data have been stored, the mesh control unit 22 does not store the newly-collected magnetism data but discards it (step S15). Collection of magnetism data is further continued. Thereafter, upon the determining unit 23 having determined that the number of sections not storing the predetermined count of magnetism data (upper limit value) or more has become smaller than eight (No in step S17), the calibration unit 24 performs offset and distortion computation using the collected magnetism data (step S19).

Using the method of collecting magnetism data according to the present embodiment enables offset and distortion of the magnetic sensor to be obtained with a small amount of computation, and the magnetic sensor calibration device 2 that can accurately compute offset and distortion can be provided.

Note that the information processing device 1 may be provided with multiple magnetic sensor calibration devices 2. Offset and distortion can be computed more precisely by comparing the offset and distortion computed at the calibration units 24 that the multiple magnetic sensor calibration devices 2 each have.

### Embodiment 2

Embodiment 2 will be described below. Note that points of difference as to Embodiment 1 will be primarily described in the present embodiment, components having the same functions as components used in Embodiment 1 are denoted by the same characters, and description thereof will be omitted.

In the present embodiment, prior calibration, where the offset value is made to be smaller than the value of geomagnetism, is performed in a case where the offset value of the magnetic sensor is larger than the value of geomagnetism before calibration. Offset and distortion calibration is then performed. According to the configuration above, an information processing device that can accurately compute the offset and distortion of the magnetic sensor with a small amount of computation can be provided.

[Information Processing Device 1A]

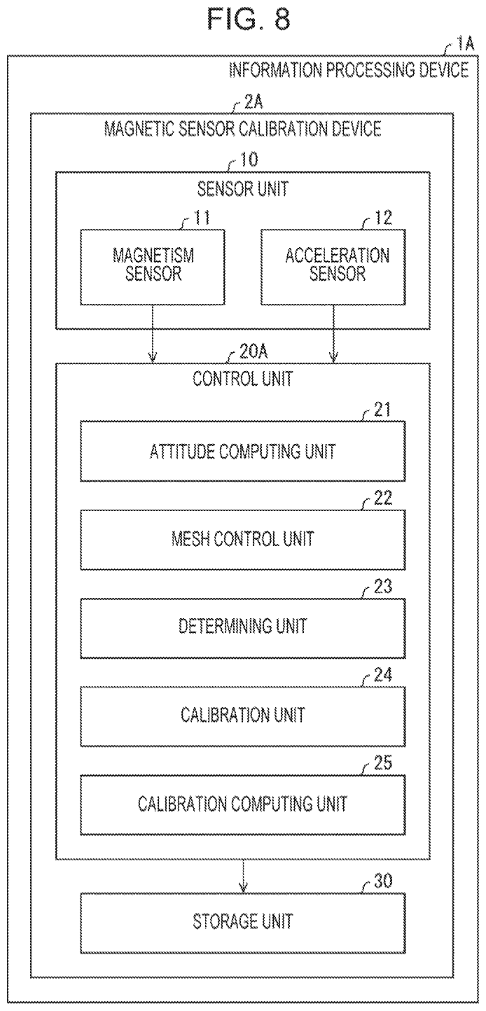

FIG. 8 is a block diagram of the configuration of an information processing device 1A according to the present embodiment. The information processing device 1A is provided with a magnetic sensor calibration device 2A instead of the magnetic sensor calibration device 2 that the information processing device 1 (FIG. 1) was provided with. The magnetic sensor calibration device 2A is provided with a control unit 20A instead of the control unit 20 that the magnetic sensor calibration device 2 was provided with. Other configurations of the information processing device 1A are the same as with the information processing device 1. The control unit 20A differs from the control unit 20 with regard to the point that it is provided with a calibration computing unit 25 in addition to the configuration of the control unit 20.

The calibration computing unit 25 computes the difference between the maximum value and minimum value of each of the multiple axes, from the multiple magnetism data that the control unit 20A has obtained from the magnetic sensor 11, before the attitude computing unit 21 performs attitude computation. In the present embodiment, the magnetic sensor 11 is assumed to be a triaxial magnetic sensor. That is to say, the calibration computing unit 25 computes the difference between the maximum value and minimum value of values of the X axis, the difference between the maximum value and minimum value of values of the Y axis, and the difference between the maximum value and minimum value of values of the Z axis, from the multiple pieces of magnetism data that the control unit 20A has obtained from the magnetic sensor 11. Note that in a case where the magnetic sensor 11 is a biaxial magnetic sensor, the calibration computing unit 25 computes the difference between the maximum value and minimum value of values of the X axis and the difference between the maximum value and minimum value of values of the Y axis, from the multiple pieces of magnetism data that the control unit 20A has obtained from the magnetic sensor 11.

Upon the difference between the maximum value and minimum value for each axis exceeds a threshold value set beforehand at the calibration computing unit 25, the attitude computing unit 21 performs attitude computation, following which the mesh control unit 22 generates a mesh and performs processing of storing magnetism data in each section, in the same way as described in Embodiment 1. Note that an ideal value for the difference between the maximum value and minimum value for each axis in the magnetism data is equivalent to twice the value of geomagnetism, and for the threshold value as an example, one time the magnitude of the value of geomagnetism may be set for the difference between the maximum value and minimum value.

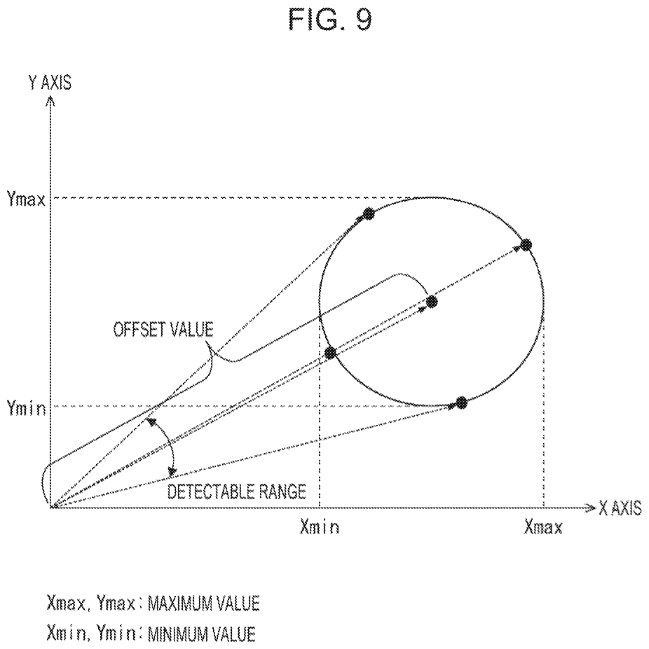

FIG. 9 is a diagram illustrating a detectable range of attitude angle that can be measured by the magnetic sensor before prior calibration, in a case where the offset value of the magnetic sensor according to the present embodiment is greater than the value of geomagnetism. In a case where the offset value of the magnetic sensor before calibration is greater than the value of geomagnetism, the attitude angle that can be measured by the magnetic sensor becomes extremely narrow, as illustrated in FIG. 9. The offset value of the magnetic sensor in FIG. 9 represents the distance from the origin coordinate of the collected magnetism data (the position where the Y axis and X axis intersect) to the coordinates at the center of a circle plotted by a set of magnetism data. The radius of the circle plotted by the set of magnetism data is the value of geomagnetism. Note that while a case is illustrated in FIG. 9 where the offset value of magnetism data is greater than the geomagnetism using two-dimensionally projected magnetism data, this can be represented three-dimensionally as well. A case where the offset value is greater than geomagnetism three-dimensionally differs with regard to the point that the set of magnetism data is plotted as a sphere instead of a circle.

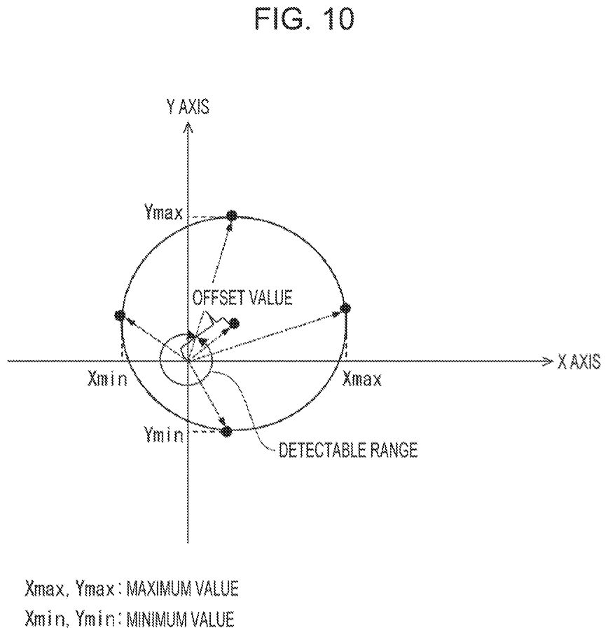

FIG. 10 is a diagram illustrating a detectable range after prior calibration, according to the present embodiment. As illustrated in FIG. 10, reducing the offset value of the magnetic sensor 11 by prior calibration broadens the attitude angle that the magnetic sensor 11 can measure.

Note that prior calibration can be carried out by subtracting the offset value from the collected magnetism data. Specifically, an average value is calculated from the maximum value and minimum value for each of the multiple axes (offset value for each axis), from the set of magnetism data that has been collected. Prior calibration is then performed by subtracting the offset value of each axis from the value of each axis in the collected magnetism data.

Specifically, with the offset value of the X axis as Xoffset, the maximum value of magnetism data on the X axis as Xmax, the minimum value of magnetism data on the X axis as Xmin, the offset value of the Y axis as Yoffset, the maximum value of magnetism data on the Y axis as Ymax, and the minimum value of magnetism data on the Y axis as Ymin, the following can be expressed.

Xoffset=(X max+X min)/2

Yoffset=(Y max+Y min)/2

From the configuration above, in a case where the offset value of the magnetic sensor 11 before calibration is greater than the value of geomagnetism, performing prior calibration to make the offset value smaller than the value of geomagnetism enables offset and distortion of the magnetic sensor 11 to be obtained with a small amount of computation, and an accurate magnetic sensor calibration device 2 to be provided.

[Information Collection Method]

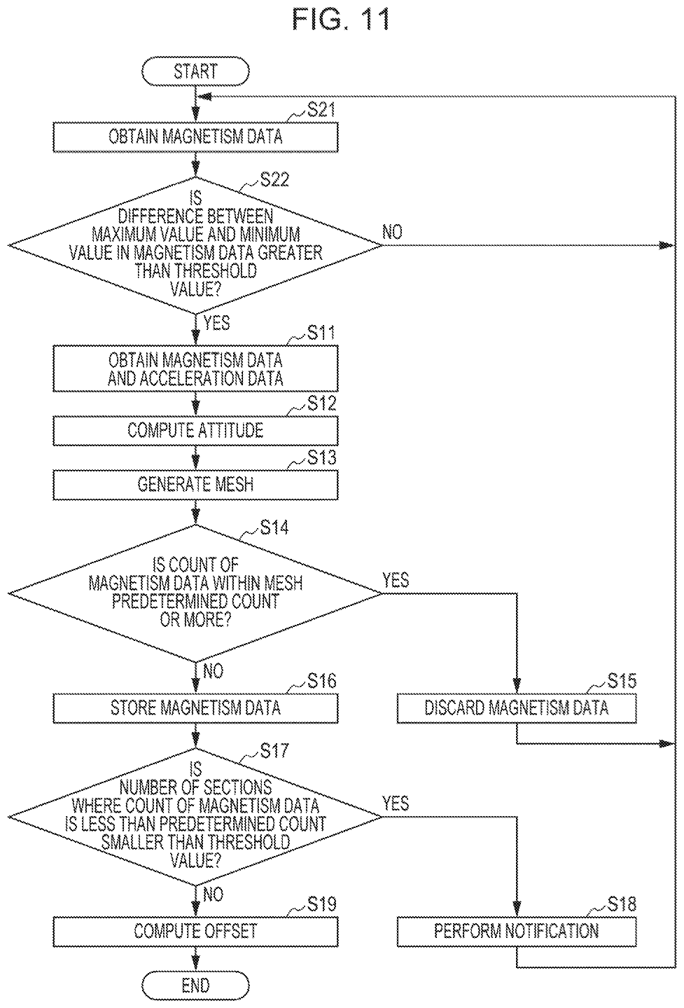

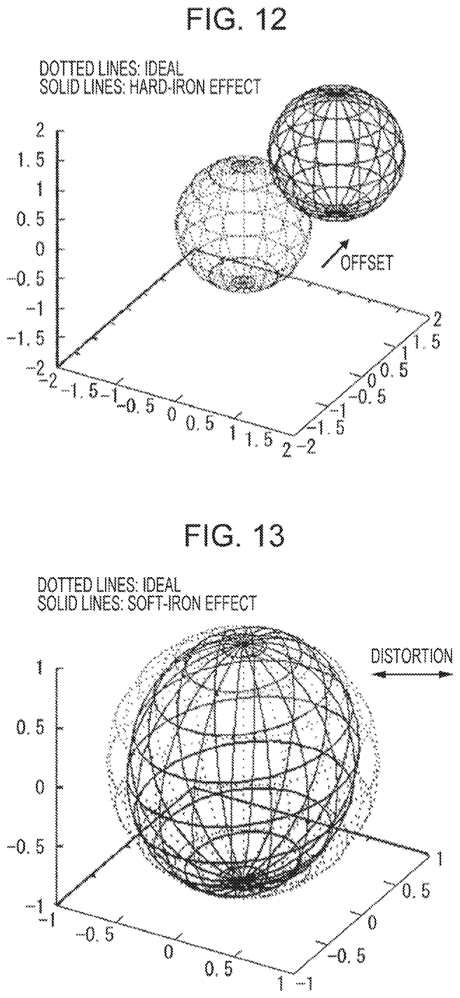

An information processing method using the information processing device 1A according to the present embodiment will be described below. FIG. 11 is a flowchart illustrating the magnetism data collection method according to the present embodiment. Note that steps performing the same processing contents as in Embodiment 1 will be omitted from description. First, the control unit 20A obtains magnetism data in step S21. The magnetism data may be obtained at the same time as acceleration data.

Next, in step S22, the calibration computing unit 25 records the maximum value and minimum value for each of the X axis, Y axis, and Z axis of the magnetism data obtained in step S21, and obtains the difference between the maximum value and minimum value of each axis. Note that the memory where the calibration computing unit 25 records the maximum value and minimum value for each of the X axis, Y axis, and Z axis of the magnetism data may be the storage unit 30, or may be memory provided separately from the storage unit 30. The calibration computing unit 25 determines whether or not the difference between the maximum value and minimum value for each axis is greater than a threshold value set beforehand. In a case of the calibration computing unit 25 determining that the difference between the maximum value and minimum value for each axis is equal to or smaller than the threshold value in step S22 (a case of No in step S22), magnetism data is obtained again.

On the other hand, in a case of the calibration computing unit 25 determining that the difference between the maximum value and minimum value for each axis is greater than the threshold value set beforehand in step S22 (a case of Yes in step S22), prior calibration is performed to make the offset value smaller than the value of geomagnetism. The flow then advances to the processing of step S11. The flow thereafter is the same processing as in Embodiment 1, so description will be omitted.

Even if the offset value of the magnetic sensor before calibration is greater than the value of geomagnetism at the time of offset computation and computation cannot be performed accurately, performing the prior calibration according to the present embodiment enables the offset value to be accurately computed.

### Third Embodiment

### Software Example

The control block (attitude computing unit 21, mesh control unit 22, determining unit 23, calibration unit 24, and calibration computing unit 25) of the information processing devices 1 and 1A may be realized by a logical circuit (hardware) formed in an integrated circuit (IC chip) or the like, or may be realized by software.

In a case of the latter, the information processing devices 1 and 1A have a computer to execute commands of a program that is software realizing each of the functions. This computer has at least one processor (control device) for example, and also has at least one computer-readable recording medium storing the program. The object of the present invention is achieved in the computer by the processor reading the program from the recording medium and executing it. A CPU (Central Processing Unit), for example, may be used as the processor. “A non-transitory tangible medium”, which is ROM (Read Only Memory) or the like for example, or further a tape, disk, card, semiconductor memory, programmable logical circuit, or the like, may be used as the recording medium. RAM (Random Access Memory) or the like to load the program to may further be provided. The program may be supplied to the computer via any transmission medium (communication network, broadcast waves, etc.) capable of transmitting the program. One aspect of the present invention may be realized in the form of data signals embedded in carrier waves realized by electronic transmission of the program.

The present invention is not restricted to the above-described embodiments. Various types of modifications can be made within the scope set forth in the claims, and embodiments obtained by appropriately combining technical means disclosed in each of the different embodiments also are included in the technical scope of the present invention. Further, new technical features can be formed by combining technical means disclosed in the embodiments.

### REFERENCE SIGNS LIST

1, 1A information processing device
2, 2A magnetic sensor calibration device
10 sensor unit
11 magnetic sensor
12 acceleration sensor
20, 20A control unit
21 attitude computing unit
22 mesh control unit
23 determining unit
24 calibration unit
25 calibration computing unit
30 storage unit
M1 through M42 section Nos.
θ pitch angle
Ψ yaw angle
ψ roll angle

1. An information processing device that collects magnetism data from a magnetic sensor, the device comprising:
a mesh control unit that generates a mesh that divides, into a plurality of sections, an orientation space where pieces of the magnetism data collected from the magnetic sensor are arrayed, based on coordinate components of the magnetism data, and stores the magnetism data in a storage unit in association with each section,
wherein a number of sections in contact with a vertex of each of the plurality of sections is three or less.

2. The information processing device according to claim 1, further comprising a determining unit that determines whether or not to continue collection of the magnetism data from the magnetic sensor, based on a number of sections storing a predetermined count of the magnetism data, out of the plurality of sections.

3. The information processing device according to claim 2, wherein the determining unit discards magnetism data collected after a count of the magnetism data stored in each of the plurality of sections reaches the predetermined count or greater.

4. The information processing device according to claim 2, wherein the determining unit performs notification processing to a user in a case where a number of sections not storing the predetermined count of the magnetism data, out of the plurality of sections, is smaller than a threshold value.

5. The information processing device according to claim 1, further comprising:
the magnetic sensor that outputs the magnetism data;
an acceleration sensor that outputs acceleration data; and
an attitude computing unit that collects each of the magnetism data and the acceleration data, and performs attitude computation before the mesh control unit generates the mesh.

6. The information processing device according to claim 1, wherein the magnetism data includes values of a plurality of axes as the coordinate components,
the information processing device further comprising a calibration computing unit that computes a difference between a maximum value and minimum value of each of the plurality of axes, from a plural pieces of magnetism data.

7. The information processing device according to claim 1, wherein the mesh control unit stores the magnetism data in the storage unit, in association with identification information for identifying each of the plurality of sections, and a count of the magnetism data stored in each of the plurality of sections.

8. An information processing method of an information processing device that collects magnetism data from a magnetic sensor, the method comprising:
a mesh control step of generating a mesh that sections, into a plurality of regions, an orientation space where pieces of the magnetism data collected from the magnetic sensor are arrayed, based on coordinate components of the magnetism data, and storing the magnetism data for each section in a storage unit,
wherein, in the mesh control step, sectioning is performed in which a number of sections in contact with a vertex of each of the plurality of sections is three or less.

9. The information processing method according to claim 8, further comprising a determining step of determining whether or not to continue collection of the magnetism data from the magnetic sensor, based on a number of sections not storing a predetermined count of the magnetism data, out of the plurality of sections.

10. The information processing method according to claim 9, wherein, in the determining step, magnetism data collected after a count of the magnetism data stored in each of the plurality of sections reaches the predetermined count or greater is discarded.

11. The information processing method according to claim 9, wherein, in the determining step, notification processing to a user is performed in a case where sections not storing the predetermined count of the magnetism data, out of the plurality of sections, is smaller than a threshold value.

12. The information processing method according to claim 8, further comprising:
an attitude computing step in which attitude computation is performed using the magnetism data and acceleration data obtained from an acceleration sensor, before the mesh control step.

13. The information processing method according to claim 8, wherein the magnetism data includes values of a plurality of axes as the coordinate components,
the method further comprising a calibration computing step in which a difference between a maximum value and minimum value of each of the plurality of axes is computed.

14. The information processing method according to claim 8, wherein, in the mesh control step, the magnetism data is stored in the storage unit, in association with identification information for identifying each of the plurality of sections, and a count of the magnetism data stored in each of the plurality of sections.

15. A data structure that stores magnetism data collected by a magnetic sensor,
wherein section data indicating a plurality of sections obtained by dividing an orientation space where pieces of the magnetism data are arrayed, based on coordinate components of the magnetism data, and a count of magnetism data stored in each of the sections, are stored, and
wherein the section data and the count of the magnetism data are used by an information processing device, in processing of determining whether or not to continue collection of the magnetism data, based on a number of sections storing a predetermined count of the magnetism data.

16. The data structure according to claim 15,
wherein an upper limit value of a count of the magnetism data stored in each of the plurality of sections is stored, and
wherein the upper limit value is used as a determination reference for processing of discarding magnetism data collected after the count of the magnetism data has reached the upper limit value or higher, out of the magnetism data stored in each of the sections in the information processing device.
